(19) United States
(12) Patent Application Publication
(10) Pub. No.: US 2021/0154775 A1
(43) Pub. Date: May 27, 2021

(54) LEAD-FREE SOLDER FOIL FOR DIFFUSION SOLDERING AND METHOD FOR PRODUCING THE SAME

(71) Applicant: Pfarr Stanztechnik GmbH, Buttlar (DE)

(72) Inventors: Haneen DAOUD, Bayreuth (DE); Angela LOIDOLT, Voelkershausen (DE); Stephan REICHELT, Hohenroda (DE)

(73) Assignee: Pfarr Stanztechnik GmbH, Buttlar (DE)

(21) Appl. No.: 16/613,461

(22) PCT Filed: May 9, 2018
(86) PCT No.: PCT/DE2018/000132

§ 371 Date: Nov. 14, 2019

(30) Foreign Application Priority Data
May 15, 2017 (DE) 10 2017 004 626.3

(51) Int. Cl. B23K 35/26; B23K 35/02

(52) U.S. Cl. CPC B23K 35/262; B23K 35/302; B23K 35/0238

(57) ABSTRACT

The invention relates to a lead-free solder foil for diffusion soldering and to the method for its production, with which method metallic structural parts and/or metallized/metal-coated structural parts, i.e. metallic surface layers of adjacent structural parts, may be bonded to one another. The task of the invention is to provide an economic and environmentally friendly lead-free solder foil that is not hazardous to health for diffusion soldering, with which the structural parts to be soldered can be bonded to one another in such a way, in a process temperature range typical of the soft soldering, i.e. at approximately 240° C. and in soldering times of shorter than 5 minutes, without a subsequent heat treatment and without the exertion of a pressing force during the soldering, that a continuous layer of a high-melting bonding zone is obtained in the form of an intermetallic phase having a remelting temperature of higher than 400° C. The lead-free solder foil (1) according to the invention for diffusion soldering contains a solder composite material (4), which is produced by roll-plating and which is then constructed in such a way that, in a lead-free soft-solder environment of a soft-solder matrix (5), compact particles (6) of a high-melting metal component (7) are completely surrounded by lead-free soft solder (8), wherein the dispersedly distributed particles (6) of the high-melting metal component (7) have a thickness of 3 μm to 20 μm in the direction of the foil thickness, the spacings of the particles (6) relative to one another in the soft-solder matrix (5) are 1 μm to 10 μm, each of the particles of the high-melting metal component (7) is enveloped all around by a layer, 1 μm to 10 μm thick, of the lead-free soft solder (8), and the solder foil (1) has, adjacent to the metallic surface layers (3) of the structural parts (2) to be joined, an outer cladding layer (10), the layer thickness of which is 2 μm to 10 μm and which consists of soft solder (8).

The invention relates to a lead-free solder foil for diffusion soldering and to the method for its production, with which method metallic structural parts and/or metal-coated structural parts, i.e. metallic surface layers of adjacent structural parts, may be bonded to one another.

The reliability of solder junctions in electronics and therefore especially in power electronics now requires very good mechanical, electrical and thermal properties of the solder materials and also of the bonding zones generated with them, wherein their stability at present is to be expanded to increasingly higher temperature ranges.

In this context, and for reasons of environmental protection and health safety, the international trend is directed toward the use of environmentally friendly lead-free solder materials that are not hazardous to health.

In the course of the switch to lead-free solders, largely based on tin, numerous solder variants have been developed, which in comparison to the lead-containing alloys indeed also have good mechanical, electrical and thermal properties, but they melt in the range of approximately 214° C. to 250° C., and so the stability of their good properties is limited to areas of application up to approximately 150° C.

For higher working/operating temperatures, no lead-free solder is known at present that unites the thermal stability of the properties needed in power electronics with the necessary reliability and cost effectiveness.

Therefore the need exists in high-temperature applications, i.e. especially also at working temperatures above 250° C., to develop new lead-free solder foils that can be used inexpensively and that meet the requirements of temperature control imposed in power electronics, in order on the one hand to avoid, during the welding process, damaging the assemblies to be joined and on the other hand, also under the viewpoint of cost effectiveness, to achieve a solder bond that is stable at high temperatures and also ensures a high thermal reliability of the bonding zones between the adjacent structural parts.

At present, the highly expensive eutectic Au80Sn20 solder with a melting temperature of 280° C. is sometimes used in electronics and in the related branches of industry.

However, broad application of this Au80Sn20 solder, for example for soldering of Si semiconductor circuits in switches for power electronics, is not possible, for reasons of the high costs of the solder material.

In this connection, the joining of substrates coated with gold and/or silver and of electronic structural parts with use of tin-containing gold or indium solders, is also specified in U.S. Pat. No. 7,659,614 B2. During use of these materials, gold and/or silver form, from the metallization layers containing tin and/or indium, bonding zones having higher melting temperatures than the originally used solders. The joining process takes place at 250° C. at least and lasts for 10 minutes to 30 minutes, but in the process a light contact pressure is always necessary, but this also makes the soldering process even more complex.

Therefore, on the basis of the technological complexity and high material costs for the coatings and the solder, the use of this teaching disclosed in U.S. Pat. 7,659,614 B2 remains greatly limited for large-scale industrial application.

Since no technically and economically acceptable lead-free alternative to the gold-containing alloys has been available heretofore in industry, exempting regulations have been passed, according to which lead has still been permissible to date in high-melting solders (i.e. lead-base solder alloys with a proportion by mass of at least 85% lead) despite the international needs for environmentally friendly lead-free solder materials that are not hazardous to health, and therefore are still frequently applicable in practice despite the health concerns and the concerns about environmental protection.

As a consequence of the increasing use of semiconductors with wide band gaps (wide-band-gap semiconductors), such as those of SiC or GaN, for example, the working temperatures of which may rise well above 200° C., an increasing demand is nevertheless developing for solder compounds that meet the technical requirements in the area of high-temperature applications, i.e. working temperatures in the range of 150° C. to 400° C.

As the approach to this problem, sintering techniques among others have been developed by means of which mostly silver-containing pastes are used for joining of electronic structural parts. In contrast to soldering, however, a pressing force is absolutely necessary in this joining technique. However, this additional technological component, “pressing force”, is also a major reason that it has also not been possible heretofore to introduce the sintering technique on a large scale.

A further alternative is opening up with the use of reaction solders. These are reactive multi-layer systems constructed from layers, a few nanometers thick, of at least two different materials. After an activation, the diffusion between the layers begins and develops rapidly into an exothermic reaction. This supplies the heat necessary for melting of a solder. For this purpose, very thin layers (much thinner than 1 μm) of two matching metals must be deposited alternately one on the other that, on the whole, foils having a total thickness of 40 μm to 150 μm are constructed, the outer layers of which, however, consist of a solder. Isolated shaped solder pads may be formed from these layered foils. Alternatively, these metals may also be deposited alternately on a structural part to be soldered, wherein the outer layer must again be a solder. The joining process is started by ignition of the reactive layers, wherein the speed and quantity of heat can be controlled only by the layer structure and therefore is to be defined individually for each conceivable solder application as early as during fabrication of the shaped pads or coating of the structural parts to be soldered, thus meaning a great hindrance for a broad and universal application of this technique.

A variant of the broadly applied technique of soft soldering is diffusion soldering, although during use of the conventional technique it takes place with addition of various technological steps, such as the application of external pressing force or subsequent heat treatment or by longer solder profiles. As a result of such a technique, a substance deviating from the original composition of the soft solder and firmly connecting the structural parts to be joined is formed during the soldering process, wherein its melting temperature is higher than that of the solder material being used. For formation of this new substance, the high-melting intermetallic phase, a further metal, such as copper, for example, is needed in addition to the low-melting metal, such as tin, for example, commonly used in the solder material, wherein the intermetallic phases having melting temperatures higher than that of the low-melting metal are constructed by diffusion into one another.

From DE 10 2007 010242 A1, a method is known for bonding of two metal layers by means of a diffusion soldering process. This approach disclosed in DE 10 2007 010242 A1 requires that each metal layer already be structured in a particular way to begin with and at least one of them must be additionally provided with a solder layer. Only this quite special configuration of the layers, adapted to the respective components to be joined, then ensures the formation of a compact, correctly positioned bonding zone of such an intermetallic phase, without the need for an additional pressing force to be exerted once again during the soldering process. Therefore this approach, also disclosed in DE 10 2007 010242 A1, is limited to only quite special applications, such as, for example, the soldering of chips onto wafers.

From U.S. Pat. No. 8,348,139 B2, multi-layer solder foils for diffusion soldering are also known that are constructed from a metallic core, which consists of pure metals or their alloys with a melting point of higher than 280° C., and which are bonded on both sides with like or different layers, consisting of tin-base or indium-base solders, wherein the thickness of the solder layers being used amounts to at least 5 μm.

In these multi-layer solder foils according to U.S. Pat. No. 8,348,139 B2, the diffusion soldering process takes place at 300° C. to 380° C. in 5 minutes to 8 minutes. Subsequently, however, in order to ensure a continuous layer of intermetallic phases, yet another heat treatment of the joined components must be applied. In this approach, a layer thickness, not yet more closely defined, of the metallic core material, is obtained that remains after the heat treatment.

Furthermore, also from US 2006 186550 A, multi-layer solder foils for the diffusion soldering are known that are applied from a metallic core, which may comprise Ag, Au, Cu or Ni, onto the layers on both sides, consisting of tin-base, indium-base or bismuth-base solders. During the diffusion soldering process, the two soft-solder layers melt and react with the full-surface core material. According to the approach of US 2006186550 A, the applied layers are from 1 μm to at most 20 μm click, so that the transformation of the molten phase into intermetallic phases proceeds so far within a practical duration of the soldering process (of approximately 10 minutes at 240° C.) that the adhesion of the soldered components remains assured in a subsequent process step at 260° C.

The diffusion soldering process itself, as well as the reliability of the resulting bonding layer, has also been investigated in publications, including N. Oeschler and C. Ehrhardt (N. Oeschler et al.: Diffusionslöten-Technologie für hochzuverlässige Chip-Substrat-Verbindungen [Diffusion Soldering Technology for Highly Reliable Chip-Substrate Bonds], Weichlöten 2013, DVS-Berichte Volume 290, pp. 55-61 and C. Ehrhardt et al.: Prüfverfahren der Verbindungstechnik von Leistungselektronischen Modulen [Test Methods for the Bonding Technique of Power Electronic Modules], Weichlöten 2013, DVS-Berichte Volume 290, pp. 43-51). The results described in these publications are only for semiconductor-substrate bonds coated with copper/tin and were also to be achieved only by application of a pressing force.

In U.S. Pat. No. 9,620,434 B1, the joining of power electronic structural parts by means of diffusion soldering, which is suitable for working temperatures above 250° C., is likewise specified. For this purpose, two layer systems are used, respectively consisting of a high-melting and low-melting metal layer, which are placed on the components to be bonded. If necessary, the entire system is also constructed by addition of high-melting and low-melting metal particles between the metal layer and then heated. The disadvantage of this approach consists in that the complete transformation of the molten phase of the solder material into intermetallic compounds/intermetallic phases is possible only by a distinct prolongation of the conventional soldering times, i.e. necessarily requires a process duration of longer than 30 minutes for use of the approach according to U.S. Pat. No. 9,620,434 B1.

According to US 2017/0080662 A1, for the bonding of substrates, in this case especially of power electronic structural parts exposed to thermal cycles having working temperatures of higher than 250° C., a composite bonding layer is used that has an inner bonding region and an outer bonding region, which is positioned around the inner bonding region, wherein the material of the inner bonding region has a greater modulus of elasticity than the material of the outer bonding region; with a metal matrix, wherein one part of the metal matrix is positioned in the outer bonding region and one part of the metal matrix is positioned in the inner binding region, wherein the modulus of elasticity of the metal matrix is greater than the modulus of elasticity of the soft-material elements but smaller than the modulus of elasticity of the hard-material elements. The focus of this approach, presented in US 2017/0080662 A1, lies on the equalization of stresses between materials having different thermal expansion coefficients.

A special case of this middle substrate, referred to as composite joining layer, also includes a diffusion-solder bonding. However, since no particulars about the joining process and about the joining duration as well as about the structure of the achieved junction are provided in the description of the aforesaid invention, a soldering process duration that is standard in the prior art, i.e. a soldering process duration of longer than 30 minutes, must also be assumed in this approach, which according to the prior art is necessary in order to achieve complete transformation of the molten solder material into intermetallic phases.

From a further publication, that of A. Syed-Khaja (A. Syed-Khaja et al.: Process optimization in transient liquid phase soldering (TLPS) for an efficient and economical production of high temperature power electronics, CIPS 2016, pp. 187-193), the use is known of respectively one individual shaped solder pad of conventional solder alloys for diffusion soldering of substrates having a semiconductor module. In that publication, it is explained that the use of thin shaped solder pads (25 μm) of a conventional SnCu solder containing no more than 3% copper leads, without application of pressing force, to a complete formation of the high-melting intermetallic bonding zone, but somewhat longer soldering times are needed for the purpose and at least one structural part is necessary that is metallized with copper and has adapted roughness. In the use of shaped solder pads consisting on both sides of copper plated with pure tin (Sn 20 μm/Cu 35 μm/Sn 20 μm), however, only a partial transformation into a high-melting phase was achieved, i.e. a soft-solder content with correspondingly lower melting temperature remained on the bonding zone. Only by use of structural parts metallized with copper did this transformation take place completely. All results were achieved only after a soldering time of 22 minutes at a temperature of 260° C. using structural parts having an adapted roughness.

In the publication entitled “Prüfverfahren der Verbindungstechnik von Leistungselektronischen Modulen” [Test Methods for the Bonding Technique of Power Electronic Modules], Weichlöaten 2013, DVS-Berichte Volume 290, pp. 43-51)., Weichlöaten 2013, DVS-Berichte Band 290, S. 43-51, C. Ehrhardt et al. report that conventional lead-free solder pastes, such as SnAgCu, for example, must additionally be mixed homogeneously with high-melting powders, such as copper, for example, for realization of the diffusion soldering process. In the process, the molten tin-base solder of the lead-free solder paste dissolves the copper powder and makes it possible to form the intermetallic phases Cu6Sn5 and Cu3Sn. With use of these lead-free solder pastes mixed with high-melting powders, the molten phase is transformed completely into intermetallic phases by application of a pressing force during the diffusion soldering process. The melting points of the two phases formed in this way are 415° C. and 676° C. respectively. However, their pore-free formation is contingent upon not only the pressing force during the soldering process but also a very homogeneous mixing of the two needed components, solder paste and powder.

In Patent Specification EP 1337376 B1, a solder paste is described that is used as a soldering agent. This solder paste contains, in addition to the solder material, insulating cores coated with metal, which have a high melting temperature. According to the approach of EP 1337376 B1, the solder metal reacts completely with the metallization of the cores during the soldering process and, based on the diffusion soldering process, forms intermetallic phases, which then surround the high-melting cores. The resulting solder seam has a heterogeneous structure on the whole, which acts negatively on the thermal conductivity of the bonding zone obtained with this approach.

In WO 96/19314, a powder mixture is specified in which the solder metal consists of high-melting and low-melting metal components, the grain-like or flake-like filler components of which are admixed as an additive. In general, metal powders or even metal granules are very expensive to produce and in addition have a broad dispersion range of dimensions, so that classification processes must be additionally interposed, and beyond this a homogeneous intermixing of metal powder is not unproblematic and therefore is very complex. According to WO 96/19314, the powder mixture itself should then be used, preferably as a suspension in liquid organic solvents or as a paste. A filling component finding use in this connection then has the task of limiting the thickness of the intermetallic phases formed during the diffusion soldering to a few μm. It must therefore be provided, depending on wettability, with corresponding coatings that promote or retard the binding, and be mixed very homogeneously with the metal components. In special embodiments/special designs, it also is possible, according to WO 96/19314, to press the aforesaid solder metal consisting of powders to foils, from which shaped solder pads are them stamped out that are placed between the objects to be bonded. The production of such foils having a homogeneous distribution of the powders used, i.e. the powder metallurgy, is vary laborious and cost-intensive, wherein, during pressing, i.e. in the powder-metallurgical process, the theoretical density is unattainable or can be attained only with great difficulty, i.e. with high cost outlay.

The disadvantage of all embodiments of this approach according to WO 96/19314 is that, in addition to the two metal components described above, a filler component is necessary in order to achieve the desired intermetallic phases. In addition, according to the description of this approach, a soldering process duration of longer than 30 minutes is also necessary in this approach, in order to achieve a complete transformation of the molten solder into intermetallic phases, as is alternatively a subsequent tempering process.

For better wetting of the surfaces, the addition of a fluxing agent is further considered to be advantageous during the soldering process. However, as regards the work safety and the health protection, this fluxing agent has the disadvantage that, according to the description in WO 96/19314, organic acid is formed, which must necessarily be removed in an additional work cycle following the soldering process.

In summary, it must therefore be stated that the inexpensive lead-free soft solders currently used in power electronics and for other areas of operation are able to cover only an operating temperature range of up to approximately 150° C. For the operating temperature range of the soldered structural elements higher than 150° C., no lead-free solder alternative to the gold-containing solder alloys has been available heretofore that is technically and economically reasonable and that unites the thermal stability required in power electronics with the necessary reliability and reasonable cost-effectiveness, i.e. within shorter soldering times, i.e. typical for soft solders, and without additional process parameters, such as, for example, an additional pressing force or an additional, subsequent heat treatment.

In this connection, the need therefore exists to provide new lead-free solders, if at all possible as solder foil, so that these can then also be used in inexpensive and technological manner in the form of shaped solder pads.

The task of the invention is therefore to develop an economically reasonable and environmentally friendly lead-free solder foil that is not hazardous to health for diffusion soldering as well as a method for its production, which with a soldering profile typical of the soft soldering, i.e. with avoidance of long soldering times, and also without a subsequent heat treatment and without the exertion of a pressing force during the soldering, with simultaneous avoidance of pores, is intended to bond the metallic/metallized surface layers of the structural parts to be soldered with one another in such a way that a high-melting bonding zone having a remelting temperature of higher than 400° C. is obtained, wherein, by means of the lead-free solder foil to be developed, even electrically conducting ribbons in the bonding region can be additionally coated, so that, in the bonding region of the ribbons, the remelting temperature of the high-melting bonding zone formed after the soldering process is higher than 400° C. and, in addition, for special applications, in a special design, the lead-free solder foil is also intended to be provided with an adapted, resulting, thermal expansion coefficient, in order to absorb the thermal stresses introduced by the soldering and also developed during operation of the structural part, and, additionally, to simultaneously increase the mechanical flexibility of the bonding zone obtained after the soldering process.

According to the invention, this task is accomplished by a lead-free solder foil 1 for diffusion soldering and a method for its production, by means of which metallic structural parts 2 and/or metallized/metal-coated structural parts 2, i.e. metallic surface layers 3 of adjacent structural parts 2, can be bonded to one another, and which is characterized in that the lead-free solder foil 1 is constructed compactly as solder bonding material 4 in such a way that, in a lead-free soft-solder environment, a soft-solder matrix 5, particles 6 of a high-melting metal component 7, a hard-solder component 7, are dispersedly distributed in such a way that each of the particles 6 is completely surrounded by lead-free soft solder 8, in order to bring about, in a customary soft-soldering process, a complete transformation of the soft solder 8 of the soft-solder matrix 5 into intermetallic phases 9, which have a melting temperature of higher than 400° C.

The compact lead-free solder foil 1 according to the invention, produced as a solid composite, includes all material necessary for the construction of the high-melting intermetallic phase, wherein the distribution according to the invention of the material needed for the construction of the high-melting intermetallic phase, in conjunction with the compact construction, according to the invention, as solder foil 1, has the effect that, in a lead-free soft-soldering process at temperatures of approximately 240° C., a very rapid and pore-free formation of a high-melting intermetallic bonding zone 16 having remelting temperatures of higher than 400° C. is achieved.

In this connection, it is essential to the invention that the particles 6 of the high-melting metal component 7 dispersedly distributed in the soft-solder matrix 5 have a thickness of 3 μm to 20 μm in the direction of the foil thickness, wherein the spacings of the particles 6 relative to one another in the soft-solder matrix 5 are 1 μm to 10 μm, and each of the particles of the high-melting metal component 7 is enveloped all around by a layer of the lead-free soft solder 8 that is 1 μm to 10 μm thick.

By means of the inventive lead-free compact solder foil 1 containing particles 6 of hard solder (hard-solder particles) disposed in a soft-solder matrix 5, soft-solder environment, in conjunction with their disperse distribution and simultaneously compact embedding in this soft-solder matrix 5, a diffusion layer is created in a process time typical of the lead-free soft soldering, without long soldering times and also without subsequent heat treatment, and without the exertion of a pressing force, wherein the formation of pores is simultaneously avoided and the metallic/metallized surface layers 3 of the structural parts 2 to be soldered are bonded to one another in such a way that, between the structural parts 2 to be joined, a continuous pore-free layer of a high-melting bonding zone 16 is obtained in the form of an intermetallic phase 9, the remelting temperature of which lies above 400° C.

In this connection, it is characteristic that the soft-solder content, the soft-solder matrix 5, is not higher relative to the content of high-melting metal component 7 than is necessary in the intermetallic phases 9 to be constructed. This ratio of the percentage content of the particles 6 of the high-melting metal component 7 disposed in the solder composite material 4 to the percentage content of the soft solder 8 of the lead-free soft-solder matrix 5 surrounding the particles 6 is determined in such a way according to the stoichiometric formula of the intermetallic phases 9 to be formed from the respective starting materials that all soft solder 8 of the lead-free soft-solder matrix 5 is always transformed into the intermetallic phases 9 to be respectively constructed.

The ratio of the soft-solder content to the content of the particles 6 of high-melting metal component 7 in the soft-solder matrix 5 therefore depends on the stoichiometric formula of the intermetallic phase 9 to be respectively constructed. For example, this would be the CuSn3 and Cu6Sn5 in the case of use of the Sn/Cu combination containing 50% Sn.

It is decisive for a remelting temperature of higher than 400° C. that the entire soft-solder matrix 5 always be transformed, otherwise regions would still remain in the bonding zone 16 that would have a lower melting temperature and, according to the task, this is not desired.

In case of a different combination, for example in case of use of the Sn/Ni combination containing 43% Sn, Ni3Sn4 is formed as intermetallic phases.

In this connection, however, it is also to be noted that, after the soldering process, particles 6 of the high-melting metal component may still remain in the bonding zone 16, and the remelting temperature nevertheless remains higher than 400° C.

Via this higher content of the particles 6, i.e. by means of the high-melting residual metal that after the soldering process is incorporated in the intermetallic phase 9 as islands, e.g. of copper, the possibility exists of influencing the mechanical, electrical and heat-conducting properties of the bonding zone 16 obtained after the soldering process.

On the basis of the teaching according to the invention, it is therefore decisive merely that the entire soft-solder component must be consumed in the soldering process, transformed into intermetallic phases 9, in order to ensure a remelting temperature of higher than 400° C. after the soldering process.

For example, in case of use of an In/Ag combination for achievement of a remelting temperature of higher than 400° C., a very high silver content would be necessary. However, since it is the task of the invention to develop an economically reasonable, lead-free solder foil for diffusion soldering, this combination will not be taken into consideration in more detail.

It is also essential that the total thickness of the lead-free solder 1 be 20 μm to 0.5 mm, depending on the technological boundary conditions/desired properties of the bonding zone 16.

It is further characteristic that the solder foil 1, the solder composite material 4 has, adjacent to the metallic surface layers 3 of the structural parts 2 to be joined, an outer cladding layer 10, the layer thickness of which is 2 μm to 10 μm and which consists of soft solder 8.

This cladding layer 10, consisting of soft solder 8, functions during the soldering process to wet the surfaces/surface layers 3 of the adjacent structural parts 2 completely during the soldering process and to form, with these metallizations (e.g. Cu, Ni, Ni(P), Ni(Ag)) of the surfaces of the structural parts 2 to be joined, intermetallic phases 9.

This lead-free solder foil 1 for diffusion soldering makes it possible, with a solder profile typical of the lead-free soft soldering, for example during use of solder foils 1 of the thickness from 30 μm to 250 μm at a soldering temperature of approximately 240° C. and for soldering times of less than 5 minutes, without any subsequent heat treatment and also without the exertion of a pressing force during soldering, with simultaneous avoidance of the formation of pores, to bond the metallic/metallized surface layers 3 of the structural parts 2 to be soldered to one another in such a way that a continuous layer of a high-melting bonding zone 16 is obtained in the form of an intermetallic phase 9, which has a remelting temperature of higher than 400° C.

It is also essential to the invention that the lead-free solder foil 1 for diffusion soldering meets special technical or even technological requirements, but for economic reasons is also constructed as a multi-layer solder foil 11, wherein the individual layers of the multi-layer solder foil 11 consist alternately of the above-described solder composite material 4 and of layers, 2 μm to 100 μm thick, of a high-melting metal component 7, an intermediate layer 23, wherein even the multi-layer foil 11 in turn has, adjacent to the metallic surface layers 3 of the structural parts 2 to be joined, an outer cladding layer 10, the layer thickness of which is from 2 μm to 10 μm, and which consists of soft solder 8, and the total thickness of the multi-layer foil is from 40 μm to 1.0 mm.

By means of this special design, the multi-layer foil 11, the lead-free solder foil 1 may also be provided with an adapted, resulting thermal expansion coefficient, in order to absorb the thermal stresses introduced due to the soldering and also developed during operation of the structural part and additionally to simultaneously increase the mechanical flexibility of the bonding zone formed after the soldering process.

It is also essential that the lead-free soldering foil 1 for diffusion soldering can be used not only as a solder composite material 4 but also as a multi-layer foil 11 in the design of a shaped solder pad 12, in order, in a lead-free soft-soldering process, to function as a diffusion solder between metallic surfaces/surface layers 3 and to bond the adjacent structural parts 2 to one another in such a way that the remelting temperature is higher than 400° C.

The shaped solder pads 12 are brought to the desired shaped-pad geometry by cutting or stamping processes or else by combined stamping and bending processes from the solder foil 1 and in this way are universally usable in numerous customary soft-soldering processes, which become diffusion soldering processes solely by the use of the distributed particles 6 of the solder composite material 4 (composite material). In this way, the remelting temperature of the bonding zones is raised substantially compared with structural parts soldered conventionally with soft solder. During use of tin soft solder components and copper as the high-melting metal component, the structural elements 2 soldered with shaped solder pads 12 from solder composite material 4 are usable for the operating temperature range up to 400° C., wherein the thermal stability of the properties required in the power electronics is united with the necessary reliability and cost effectiveness.

It is also characteristic that a metallic conductor ribbon 13, which functions as an electrical conductor in the product 14 to be joined, is partly coated at the junctions 15 with the lead-free solder foil 1, not only in the embodiment as a solder composite material 4 but also in the embodiment as a multi-layer solder foil 11, so that, after the soft-soldering process, the partly coated conductor ribbon 13 bonds the adjacent structural parts 2 to one another in such a way that, after the soft-soldering process, a bonding zone 16 is obtained between the coated conductor ribbon 13 and the structural parts 2 to be bonded with this that has a remelting temperature of higher than 400° C.

For this purpose, the lead-free solder foil 1 produced according to the invention for diffusion soldering is applied on one side by partial plating on an electrically well conducting material, such as copper or aluminum, for example. From this partly plated material, it is then possible to fabricate conductor ribbons 13, which can be used, for example instead of the customary bonding wire for construction of power modules.

The lead-free solder foil 1 according to the invention for diffusion soldering is produced according to the invention by roll plating as described in the following.

Depending on the provided/intended percentage composition, soft solder and metal components are joined alternately by means of roll plating to a layer composite, wherein the metal component is plated on both sides with the soft-solder component.

The plating is begun in such a way that the layer thicknesses to be used of the components are in such a ratio relative to one another on the whole that, in the subsequent soldering process, the soft-solder content is completely incorporated, according to the invention, in the intermetallic phase.

Thereupon, further roll-plating steps are then performed, in which the respective plated material is plated with itself, so that the number of layers in the material is increased but their thickness is simultaneously reduced. The number of necessary plating steps up to the finished solder composite material 4 according to the invention is dependent on the chosen material combination of soft and hard-solder components and the desired total thickness for the shaped solder pads. Due to the numerously repeated platings, according to the invention, of the layer composite, intermingling of the individual components in the solid state takes place in such a way that tearing of the layers of one of the two components causes their fragments to become dispersed in the other, the softer component.

The structure that thus results according to the invention, in which the particle spacings according to the invention are smaller than or equal to 10 μm, ensures the short diffusion paths to be achieved according to the invention, whereby, in the subsequent lead-free soft-soldering process, in conjunction with further features, yet to be explained in the following, of the solder foil produced according to the invention, lead in a short time to complete transformation of the soft-solder components into the intermetallic phase and permit a compact, pore-free high-melting bonding zone to be formed.

The short diffusion paths achieved according to the invention, in conjunction with further advantages/features, yet to be explained in the following, of the solder foil according to the invention, even make possible the applicability of customary soft-solder profiles with the short soldering times characteristic for these.

According to the invention, intermetallic phases 9 are formed in the process that comprise a low-melting soft-solder component and a high-melting metal component/hard-solder component and that are consumed in proportions by mass corresponding to their stoichiometric formula. The components will be/are selected such that the melting point of their intermetallic phase lies between the melting points of the two components used.

The melting temperature of the soft-solder component in the case of use of tin as the basis lies in the range up to 240° C., whereas the melting temperature of the intermetallic phases 9 in the case of use of copper as the high-melting component lies above 400° C.

The solder composite material 4 resulting from multiple forming processes may also be applied if necessary in further plating steps on a high-melting metallic base material, whereby layers of solder composite material 4 and metallic intermediate layers 23 having special desired mechanical properties alternate and thereby a multi-layer foil 11 is constructed, wherein, however, a soft-solder component as the outer cladding layer 10 always forms the two outer layers.

By means of an adapted, resulting thermal expansion coefficient, such a multi-layer foil 11 is then able, for example, to absorb the thermal stresses introduced by the soldering and also developed during operation of the structural part.

For this purpose, the thickness of the solder foil 1 in the embodiment as a solder composite material 4 can always be adjusted, by the starting thicknesses of the two components, the number of plating steps and the final rolling step, to the exact thickness of the solder foil 1 or of the shaped solder pads 12 to be produced from this.

Even the thickness of the solder foil 1 in the embodiment as a multi-layer solder foil 11 can be adjusted, by the starting thicknesses of the metallic intermediate layer as well as of the layers containing solder composition material 4, the number of plating steps and the final rolling step, to the respectively desired exact dimension of the solder foil 1 or of the shaped solder pads 12 to be produced from this. According to the invention, the high-melting metal component/hard-solder component is dispersed with particle spacings smaller than or equal to 10 μm in the soft-solder component.

The outer layers of the lead-free solder foil according to the invention are always formed continuously according to the invention, as already explained, from the soft-solder component.

By the production, according to the invention, of the lead-free solder foil as part of a roll-plating process, the disadvantages of introduction of particles into a melt, which consist in particular in the achievement of a homogeneous distribution, are additionally also avoided. In the process of stirring, a homogeneous distribution is indeed still to be ensured, but during solidification this is no longer the case.

Thus a homogeneous distribution of the particles is no longer to be ensured during casting into the final mold, i.e. where do the particles “wander”?

Even during introduction of the particles, into the melt, for example, partial diffusion already takes place additionally, due to the (high) temperatures that are absolutely necessary.

Even these problems, which occur during introduction of particles into a melt, are avoided by application, according to the invention, of the process of roll-plating, a rapid and efficient method that can be controlled in a manner ensuring process safety, and that takes place at relatively low temperatures (i.e. the roll-plating is a cold-rolling method, in which the rolls are not artificially heated), so that an unwanted diffusion of the materials can be ruled out by the very production process according to the invention.

The individual layer thicknesses, and also the size and the distribution of the formed particles for subsequent complete transformation of the molten solder material into intermetallic phases as part of the diffusion soldering process according to the invention, are exactly controlled according to the invention by the roll-plating process, as described above.

By way of roll-plating, a substance-to-substance bond between the partners to be plated can be produced optimally according to the invention.

According to the invention, an ideal starting condition for the diffusion process is already established in this way before the melting of the soft solder.

In addition, the production of the material composite according to the invention is relatively very inexpensive due to the roll- plating method.

According to the invention, the various materials are bonded to one another in one process step by the roll-plating method and then, according to the invention, depending on the respective desired application and with regard to the volume and the thickness of the individual components desired according to the invention, are “modified”, i.e. comminuted, in the process “clad” and in addition simultaneously energized, as explained in the following.

The advantage of the solder composite material produced in this way according to the invention also consists in particular in that, in conjunction with the high input of mechanical energy during the working process of roll-plating, the binding capability of all ingredients of the solder composite material produced in this way according to the invention is also greatly improved, so that, in conjunction with the other features of the solder according to the invention presented here, a complete transformation of the molten material into intermetallic phases is possible during the diffusion soldering process within very soldering short process times, which are comparable with the soldering times of the conventional soldering process.

In the following, the approach according to the invention will be explained in more detail on the basis of an exemplary embodiment in conjunction with 5 figures.

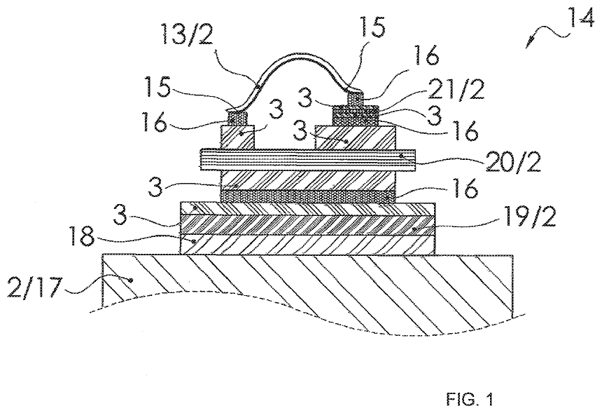

FIG. 1 shows the schematic structure of a semiconductor power switch.

The chip/semiconductor module 21 is soldered onto a conductor track, i.e. a metallic surface layer 3, which is carried by an electrically insulating layer of ceramic (DCB), the ceramic substrate 20. Its upper side is bonded to another conductor track/metallic surface layer 3 likewise situated on the substrate, which is normally realized in a bonding process using thin aluminum or copper wires/conductor ribbons 13. The ceramic substrate 20 is soldered onto a base plate 19, which is mounted on a heat sink/a cooling block 17. All surfaces/surface layers 3 to be bonded must be metallic, and the bonding zones 16 themselves must ensure heat flow to the heat sink as effectively as possible.

In the following, the use of the solder foil 1 according to the invention will be explained in more detail in conjunction with the joining process, a diffusion process for construction of the semiconductor power switch illustrated in FIG. 1.

In this connection, the lead-free solder foil 1 according to the invention in the design as a solder composite material 4 is used on the one hand for achievement of a current terminal of the semiconductor module 21 having a conductor ribbon 13 and on the other hand is also used as a shaped solder pad 12 for soldering of the semiconductor module 21 onto the DCB, the ceramic substrate 20.

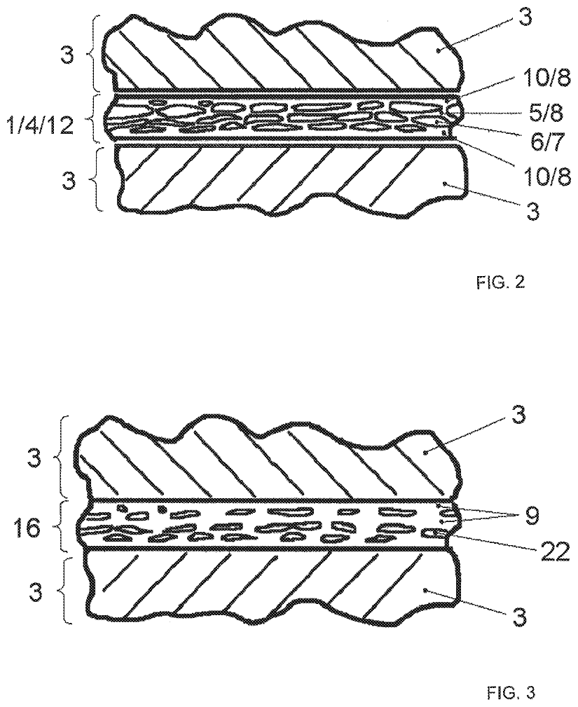

FIG. 2 shows, in a sectional diagram, the arrangement of solder foil 1 in the embodiment as a solder composite material 4 between the metallic surface layers 3, to be bonded, of the joining partners with like or different metallic surfaces/surface layers 3. In the solder composite material 4, particles 6 of copper are distributed dispersedly in a lead-free Sn soft solder matrix 5, wherein the spacing between the particles 6 is smaller than or equal to 10 μm and the uppermost and lowermost layer, the cladding layers 10, are respectively formed by the soft solder 8.

FIG. 3 schematically represents the arrangement according to FIG. 2 after the soldering process. The Sn soft solder 8 is completely transformed into intermetallic compounds/intermetallic phases 9 having a melting point higher than 400° C., wherein residues (residual metal 22) of the high-melting metal particles 6 of Cu are dispersedly distributed. Thereby it is ensured that the entire bonding zone 16 melts only at temperatures above 400° C. and in addition ensures not only the high electrical conductivity but also a very good thermal conductivity.

In the following, the lead-free solder foil according to the invention is used in the design as a multi-layer solder foil 11 for system soldering, i.e. in this case for achievement of a solder bond between the DCB, the ceramic substrate 20 and the base plate 19.

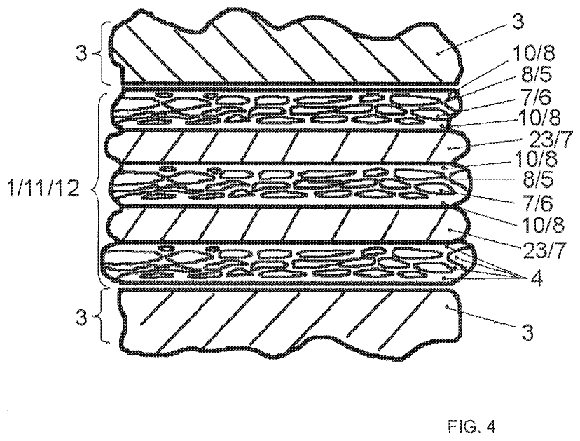

FIG. 4 shows, in a schematic sectional drawing, the arrangement of the solder foil 1 in one possible embodiment as a multi-layer solder foil 11, in the form of shaped solder pads 12, in their location relative to the joint partners, i.e. between the like or different metallic surface layers 3 to be joined of the structural parts to be joined.

In this multi-layer solder foil 11, two layers of a high-melting metal component 7, such as Cu, for example, the intermediate layers 23, are disposed between three layers of the solder composite material 4. In the solder composite material 4, Cu particles 6 are distributed dispersedly in a lead-free Sn soft solder matrix 5, wherein the spacing between the particles 6 is smaller than or equal to 10 μm, wherein the uppermost and lowermost layer of the multi-layer solder foil 11, the cladding layers 10, are again respectively formed by the soft solder 8.

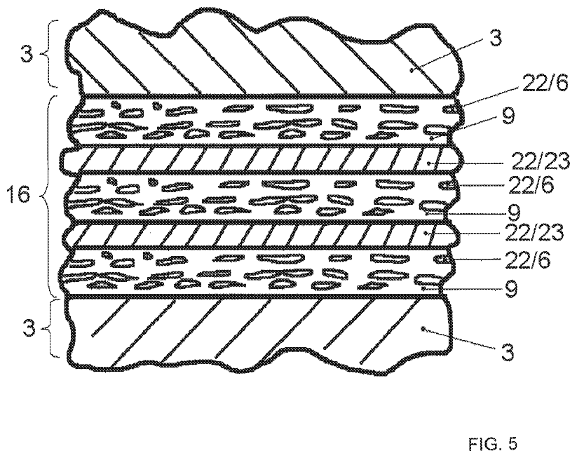

FIG. 5 now schematically shows the arrangement according to FIG. 4 after the soldering process. In the material layers comprising solder composite material 4, the Sn soft solder 8 is completely transformed into intermetallic compounds/intermetallic phases 9 having a melting point higher than 400° C., wherein, however, residues of the high-melting metal particles 6 of Cu are also dispersedly distributed.

Between them, bonded by the intermetallic phases 9, the residual metal 22, such as Cu, for example, of the intermediate layers 23 of the high-melting component 7, is present, whereby the entire bonding zone 16 melts only at temperatures above 400° C., and a very good thermal conductivity and also an adapted resulting thermal expansion of the same are ensured.

In the following, the soldering process for production of the bonding zones 16, illustrated in FIGS. 3 and 5, comprising the lead-free solder foil 1 according to the invention, will now be explained in more detail.

For chip soldering, the semiconductor modules 21, such as, for example, Si chips, SiC chips or IGBT modules, are soldered together with a DCB, a ceramic substrate 20. The said semiconductor modules 21 are normally coated with Ni or Ni(Ag), and the DCB, the ceramic substrate 20, is coated with a surface layer 3 of Cu and often additionally also with Ni. Heretofore, usually high-lead-content soldering alloys have usually been used for chip soldering, since their melting temperature ranges from 290° C. to 305° C. and the solder bond created in this way is not intended to remelt, in view of the stage-wise soldering that is standard in series production, wherein the second soldering process for system soldering takes place at temperatures of higher than 240° C. During series production, the chip soldering is usually performed in a first stage, and the system soldering takes place with a lead-free solder in a second stage. Since the high-lead-content solder has a higher melting temperature than the lead-free solder, this stage-wise soldering in the described sequence ensures that the chip-solder bond does not melt during the system soldering.

According to the present invention, a shaped solder pad 12 of solder composite material 4 having an Sn soft-solder matrix 5 and copper particles 6 distributed dispersedly therein is used for chip soldering, wherein the solder composite material 4 has, adjacent to the metallic surface layers 3 of the structural parts 2 to be joined, an outer cladding layer 10 of soft solder 8, which on one side bears on the metallic surface 3 of the chip/semiconductor module 21 and on the other side of the solder composite material 4 bears on the metallic surface/surface layers 3 of the DCB/of the ceramic substrate 20, i.e. comes in contact with these.

Compared with the chip-soldering process performed in conjunction with the high-lead-content soldering, a much lower process temperature is possible during use of the approach according to the invention, so that the heating up to 240° C., which is usual in a lead-free soft-soldering process, is sufficient here.

The Sn soft solder 8 melts at approximately 220° C., the molten phase reacts with the metallic surfaces/surface layer 3 of the adjacent structural parts 2 and within 2 minutes dissolves so much dispersed copper that the molten phase is completely transformed into the solid intermetallic phases 9, i.e. into CuSn3 and Cu6Sn5.

In this way the pore-free bonding zone 16 is obtained, the melting temperature of which lies above 400° C.

For system soldering, the DCB, the ceramic substrate 20, which is now already carrying the chip/the semiconductor module 21, is soldered together with the base plate 19. For this purpose, the base plate 19 is normally coated with a surface layer 3 of Cu, Ni, Ni(P) or Ni(Ag), and the DCB/the ceramic substrate 20, is coated with a surface layer 3 of Cu, N, Ni(P) or Ni(Ag).

According to the invention, a shaped solder pad 12 of multi-layer solder foil 11 is processed in a lead-free soft-soldering process for system soldering. The use of the multi-layer solder foil 11 offers the possibility, via the layer structure of multi-layer solder foil 11, of increasing the mechanical flexibility of the bonding zone 16 obtained after the soldering process. In the present exemplary embodiment, the shaped solder pad 12 consists of layers of a solder composite material 4 containing an Sn soft-solder matrix 5 and particles 6 of a copper metal component 7 distributed dispersedly in this Sn soft-solder matrix 5, wherein these layers alternate with layers of a high-melting metal component 7, such as copper, for example, while the outer layers of the solder composite material 4, the cladding layers 10, consist only of the Sn soft solder 8.

These outer layers of the solder composite material 4 come into contact with the metallic surfaces/ surface layers 3 of the substrate 20 and of the base plate 19, i.e. of the structural parts 2.

The Sn soft-solder 8 melts in turn at approximately 220° C. The now molten cladding layer 10 forms, together with the metallizations of the substrate 20 and of the base plate 19, the intermetallic phases 9 of CuSn3 and Cu6Sn5.

Simultaneously, the soft solder 8, which now is likewise molten, dissolves so much dispersed copper (the particles 6 of the metal component 7) in the multi-layer solder foil 11 within 2 minutes that this is completely transformed into the solid intermetallic phases of CuSn3 and Cu6Sn5. These same phases are additionally formed at the interface with the intermediate layers 23 of the high-melting metal component 7. In this way, a pore-free bonding zone 16, the melting temperature of which lies above 400° C., and which, due to remaining metallic residual layers 22, has an adapted, resulting thermal expansion coefficient, is formed after the soldering process in the region of the originally disposed multi-layer solder foil 11.

In the prior art, the chip upper side is usually joined (bonded) by fine aluminum or copper wires to the conductor track on the substrate in an ultrasonic welding process. By means of the solder foil according to the invention, this joining method may likewise be replaced by a diffusion soldering process, which takes place by analogy with the aforementioned soldering processes.

According to the invention, a conductor ribbon 13, comprising an electrical conductor such as aluminum or copper, is used for contacting the chip, and on its two connecting faces to be joined the solder composite material 4 was applied beforehand in such a way that its outer layer, consisting of Sn soft solder 8, contacts the metallic surface layer 3 of the chip/semiconductor module 21 on one side and the metallic surface layer 3 of the DCB/substrate. During heating to the corresponding temperature of a lead-free soft-soldering process, the soft solder 8 of the solder composite material 4 melts.

In the interior of the solder composite material 4, the now molten soft solder 8 dissolves so much dispersed copper (the particles 6 of the metal component 7) within 2 minutes that it is completely transformed into the solid intermetallic phases of CuSn3 and Cu6Sn5. At the interface to the metallizations (metallic surface layers 3) of the chip upper side and of the substrate, the intermetallic phases CuSn3 and Cu6Sn5 are likewise formed. Thus here also a bonding zone 16 is formed that is equivalent to that in chip and system soldering.

### LIST OF REFERENCE SYMBOLS

1 Solder foil

2 Structural parts

3 Surface layer

4 Solder composite material

5 Soft-solder matrix

6 Particles

7 Metal component

8 Soft solder

9 Intermetallic phases

10 Cladding layer

11 Multi-layer solder foil

12 Shaped solder pad

13 Conductor ribbon

14 Product

15 Junctions

16 Bonding zone

17 Cooling block

18 Thermal interface materials

19 Base plate

20 Ceramic substrate (DCB)

21 Semiconductor module (chip)

22 Residual metal (high-melting)

23 Intermediate layer (high-melting)

1-6. (canceled)

7. A method for production of a lead-free solder foil (1), produced by means of a rolling method, for diffusion soldering, in order to bond metallic structural parts (2) and/or metallized/metal-coated structural parts (2), i.e. metallic surface layers (3) of adjacent structural parts (2) to one another;
wherein, for production of the lead-free solder foil (1), the roll-plating method is repeated numerous times and is used dispersingly in such a way that a compact solder composite material (4) is obtained in which, in a lead-free soft-solder environment, i.e. a soft-solder matrix (5), particles (6) of a high-melting metal component (7), i.e. a hard-solder component, are dispersedly distributed in such a way that each of the particles (6) is completely surrounded by lead-free soft solder (8); and
wherein, for production of a solder composite material (4), soft-solder components and metal components are first joined alternately, by means of the roll-plating method, as a layer composite, corresponding to the provided/intended percentage composition of the solder composite material (4), in such a way that the metal component always becomes bonded on both sides with the soft-solder component, wherein the layer thicknesses, to be used, of the components are in such a ratio to one another on the whole that, in the subsequent soldering process, the soft-solder content is incorporated completely in the intermetal.lic phase; and
wherein, with the once plated layer composite, further roll-plating steps are subsequently repeated numerous times, in which the respective plated material is plated with itself, so that the number of layers in the material is increased but their thickness is simultaneously reduced; and
wherein the number of roll-plating steps up to the finished solder composite material (4) is repeated numerous times in dependence on the chosen material combination of soft-solder and hard-solder components and on the desired total thickness for the shaped solder pads, such
that, as a consequence of the numerously repeated roll-plating of the layer composite, intermingling of the individual components in the solid state takes place; and
that, in the process, due to tearing of the layers of one of the two components, their fragments then become dispersedly distributed, i.e. dispersed in the other, i.e. the softer component, so that, due to the numerously repeated dispersing roll-plating, a structure with particle spacings smaller than or equal to 10 μm is obtained.

8. A lead-free solder foil (1) for diffusion soldering, which was produced by the method according to claim 7, in order to bond metallic structural parts (2) and/or metallized/metal-coated structural parts (2), i.e. metallic surface layers (3) of adjacent structural parts (2) to one another;
wherein the lead-free solder foil (1) comprises compact solder composite material (4), and this compact, i.e. substance-to-substance bonded, solid solder composite material (4) is constructed in such a way that, in a lead-free soft-solder environment, i.e. a soft-solder matrix (5), particles (6) of a high-melting metal component (7), i.e. a hard-solder component, are dispersedly distributed by the numerously repeated dispersing roll-plating in such a way that each of the particles (6) is completely surrounded by lead-free soft solder (8), in order to bring about, in a customary soft-soldering process, with a soldering profile typical of the lead-free soft soldering, a complete transformation of the soft solder (8) of the soft-solder matrix (5) into intermetallic phases (9), which have a melting temperature of higher than 400° C.; and
wherein the particles (6) of the high-melting metal component (7) dispersedly distributed in the soft-solder matrix (5) have a thickness of 3 μm to 20 μm in the direction of the foil thickness, wherein the spacings of the particles (6) relative to one another in the soft-solder matrix (5) are 1 μm to 10 μm, and each of the particles (6) of the high-melting metal component (7) is enveloped all around by a layer of the lead-free soft solder (8) that is 1 μm to 10 μm thick; and
wherein the soft-solder content, i.e. the soft-solder matrix (5), is not higher in relationship to the content of high-melting metal component (7) than is necessary in the intermetallic phases (9) to be constructed, wherein this ratio of the percentage content of the particles (6) of the high-melting component (7) disposed in the solder composite material (4) to the percentage content of the soft solder (8) of the lead-free soft-solder matrix (5) surrounding the particles (6) is determined in such a way according to the stoichiometric formula of the intermetallic phases (9) to be formed from the respective starting materials that all soft solder (8) of the lead-free soft-solder matrix (5) is always transformed into the intermetallic phases (9) to be respectively constructed; and
wherein the total thickness of the lead-free solder foil (1) is 20 μm to 0.5 mm; and
wherein the solder foil (1), i.e. the solder composite material (4) has, adjacent to the metallic surface layers (3) of the structural parts (2) to be joined, an outer cladding layer (10), the layer thickness of which is 2 μm to 10 μm and which comprises soft solder (8).

9. The lead-free solder foil (1) for diffusion soldering according to claim 8,
wherein the solder foil (1) is constructed as a multi-layer solder foil (11); and
wherein the individual layers of the multi-layer foil (11) comprise alternately the solder composite material (4) and layers, 2 μm to 100 μm thick, of a high-melting metal component (7), i.e. an intermediate layer (23); and
wherein the multi-layer solder foil (11) has, adjacent to the metallic surface layers (3) of the structural parts (2) to be joined, an outer cladding layer (10), the layer thickness of which is 2 μm to 10 μm and which comprises soft solder (8); and
wherein the total thickness of the multi-layer solder foil (11) is 40 μm to 1.0 mm.

10. The method for production of the lead-free solder foil (1) for diffusion soldering according to claim 8,
wherein the solder foil (1) is constructed as a multi-layer solder foil (11), the individual layers of which are bonded to one another by means of roll-plating in such a way that these individual layers of the multi-layer solder foil (11) comprise alternately the solder composite material (4) and layers of a high-melting metal component (7), i.e. an intermediate layer (23), wherein the multi-layer foil (11) has, adjacent to the metallic surface layers (3) of the structural parts (2) to be joined, an outer cladding layer (10) that comprises soft solder (8).

11. A use of the lead-free solder foil (1) for diffusion soldering according to claim 8,
wherein this lead-free solder foil (1) is used as a shaped solder pad (12) in a lead-free soft-soldering process and, in the process, with use of a soldering profile typical of the lead-free soft soldering, the adjacent structural parts (2) are bonded to one another in such a way that the bonding zone (16) has a remelting temperature of higher than 400° C. after the soldering process.

12. The use of the lead-free solder foil (1) for diffusion soldering according to claim 8,
wherein the lead-free solder foil (1) is partly disposed at the junctions (15) of a metallic conductor ribbon (13), which functions as an electrical conductor in the product (14) to be joined, in such a way that the conductor ribbon (13) coated partly at its junctions (15) bonds, in a lead-free soft-soldering process, the structural parts (2) to be bonded with the conductor ribbon (13), to one another at the junctions (15) in such a way that, after the lead-free soft-soldering process, the bonding zone (16) has a remelting temperature of higher than 400° C.
